(19) United States
(12) Patent Application Publication
(10) Pub. No.: US 2009/0184713 A1
(43) Pub. Date: Jul. 23, 2009

(54) Tomography System with Cooled Electrically Conductive Conduits

(75) Inventor: Neil Charles Tigwell, Witney (GB)

Correspondence Address: CROWELL & MORING LLP;INTELLECTUAL PROPERTY GROUP, P.O. BOX 14300, WASHINGTON, DC, 20044-4300, US

(73) Assignee: Siemens Magnet Technology Ltd., Witney (GB)

(21) Appl. No.: 12/332,718

(22) Filed: Dec. 11, 2008

(30) Foreign Application Priority Data
Jan. 21, 2008 (GB) 0801003.5

(51) Int. Cl. G01R 33/28

(52) U.S. Cl. 324/318

(57) ABSTRACT

In a tomography system having a superconducting magnet and gradient coils, a cooling arrangement for cooling the gradient coils includes a cooling circuit which itself comprises an outward branch carrying cooling fluid to the gradient coils and a return branch carrying cooling fluid away from the gradient coils. At least part of each of the outward and return branches is formed of an electrically conductive conduit. The conduits provide electrical connections from a power supply to the superconducting magnet. In one embodiment, a first end of the bore of the first electrically conductive conduit is fluidly coupled to the bore of the outward branch; and a first end of the bore of the second electrically conductive conduit is fluidly coupled to the bore of the return branch. An electrically isolating bridging conduit is fluidly coupled between second ends of the first and second electrically conductive conduits.

The present invention relates to a power supply coupling system of the type that, for example, is used to couple a power supply to a circuit of a tomography system for example a magnetic resonance imaging system, requiring electrical power, such as superconducting magnet requiring electrical power for energisation thereof.

In the field of nuclear Magnetic Resonance Imaging (MRI), a magnetic resonance imaging system typically comprises a superconducting magnet, a gradient coil system, field coils, shim coils and a patient table. The superconducting magnet is provided in order to generate a strong uniform static magnetic field, known as the B₀ field, in order to polarize nuclear spins in an object under test. The gradient coil system typically comprises three paired orthogonal coils disposed within the superconducting magnet in order to produce gradient magnetic fields. When in use, the gradient magnetic fields collectively and sequentially are superimposed on the static magnetic field in order to provide selective spatial excitation of an imaging volume associated with the object under test.

During manufacture of the superconducting magnet, at maintenance intervals and/or when installing the superconducting magnet, it is necessary to energize the superconducting magnet to generate a desired static magnetic field, typically using a Direct Current (DC) power supply. The process of supplying electrical current to the coils of the superconducting magnet in a controlled manner in order to control so-called “boil-off” of a cryogen used to cool the superconducting magnet is known as “ramping”. Similarly, it is necessary to provide electrical power to the gradient coils in order to operate them.

However, the current-carrying electrical leads required for ramping the superconducting magnet are heavy due to the need for the leads to possess a large cross-sectional area in order to prevent overheating of the leads. For this and other qualitative reasons, the so-called “ramp leads” are expensive.

Similarly, due to the high electrical currents involved, leads used to power the gradient coils also possess large cross-sections areas and are heavy and expensive.

According to a first aspect of the present invention, there is provided a tomography system comprising a superconducting magnet and gradient coils, and a cooling arrangement for cooling the gradient coils by passage of cooling fluid therethrough. The cooling arrangement comprises a cooling circuit which itself comprising an outward branch carrying cooling fluid to the gradient coils and a return branch carrying cooling fluid away from the gradient coils. Each of the outward branch and the return branch comprises a fluid-carrying conduit. At least part of each of the outward branch and the return branch is formed of an electrically conductive conduit; and electrical connections from a power supply to the superconducting magnet are provided through the electrically conductive conduits.

According to a second aspect of the present invention, there is provided a tomography system comprising a superconducting magnet and gradient coils, and a cooling arrangement for cooling the gradient coils by passage of cooling fluid therethrough. The cooling arrangement comprises a cooling circuit, itself comprising an outward branch carrying cooling fluid to the gradient coils and a return branch carrying cooling fluid away from the gradient coils. Each of the outward branch and the return branch comprises a fluid-carrying conduit. Electrical connections from a power supply to the superconducting magnet are provided through first and second electrically conductive conduits. A first end of the bore of the first electrically conductive conduit is fluidly coupled to the bore of the outward branch; and a first end of the bore of the second electrically conductive conduit is fluidly coupled to the bore of the return branch. An electrically isolating bridging conduit is fluidly coupled between second ends of the first and second electrically conductive conduits, thereby providing a cooling circuit which cools the first and second electrically conductive conduits.

According to a third aspect of the present invention, there is provided a tomography system comprising a superconducting magnet and gradient coils, and a cooling arrangement for cooling the gradient coils by passage of cooling fluid therethrough. The cooling arrangement comprises a cooling circuit which itself comprises an outward branch carrying cooling fluid to the gradient coils and a return branch carrying cooling fluid away from the gradient coils. Each of the outward branch and the return branch comprises a fluid-carrying conduit. At least part of each of the outward branch and the return branch is formed of an electrically conductive conduit. Electrical connections from a power supply to the gradient coils are provided through the electrically conductive conduits.

It is thus possible to provide a power supply coupling system providing electrical power to a circuit of a tomography system that is relatively low-cost yet does not result in the electrical conductors overheating. By using fluid-carrying conduits that conduct electricity, it is possible to obviate the need for “solid” electrical leads due to the shared use of conduits, thereby reducing the weight and cost of electrical conductors used. In some embodiments, it is also possible to reduce space requirements by obviating the need for a set of “solid” electrical conductors and the need to organize location of the leads so as not to create a trip hazard. Furthermore, by reducing the need for a set of electrical conductors, shipping costs are reduced and logistical considerations associated with providing the electrical conductors on site are simplified.

At least one embodiment of part of the invention will now be described, by way of example only, with reference to the accompanying drawings, in which:

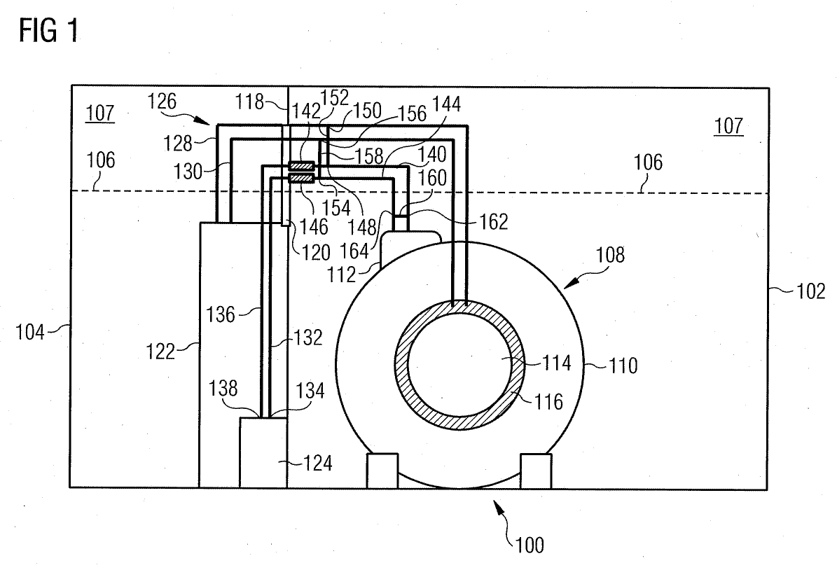

FIG. 1 is a schematic diagram of part of a Magnetic Resonance Imaging system employing current conductors constituting an embodiment of the invention;

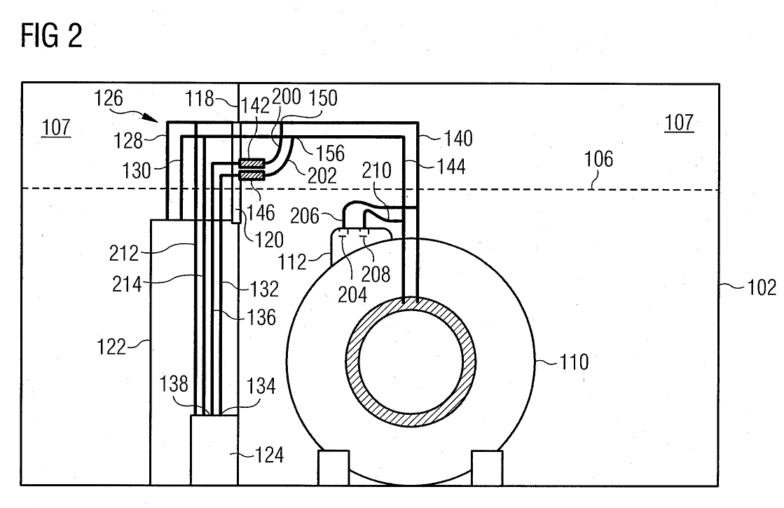

FIG. 2 is a schematic diagram of part of a Magnetic Resonance Imaging system employing current conductors constituting another embodiment of the invention; and

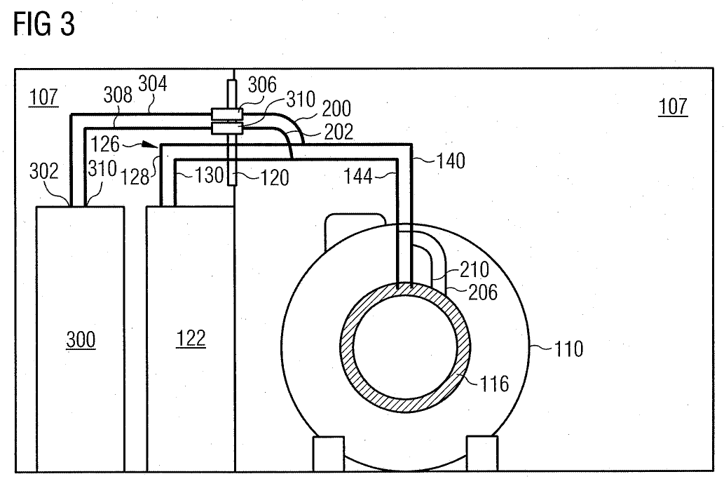

FIG. 3 is a schematic diagram of a Magnetic Resonance Imaging system employing current conductors constituting a further embodiment of the invention.

Throughout the following description identical reference numerals will be used to identify like parts.

Referring to FIG. 1, a Magnetic Resonance Imaging (MRI) system 100 is, in this example, distributed between two rooms: a scan room 102 that is isolated from a Radio Frequency (RF) perspective, for example using a so-called Faraday cage, and an equipment room 104. Both rooms comprise a false ceiling 106 providing a ceiling void 107 for concealment purposes that will become apparent later herein. A superconducting magnet unit 108 is located in the scan room 102, the superconducting magnet unit 108 comprising a cryostat 110 that houses a superconducting magnet (not shown) therein. The cryostat 110 is equipped with a mechanical refrigerator (also not shown) disposed within a turret 112 formed to a side of the cryostat 110. The cryostat 110 has a central bore 114 in which pairs of gradient coils 116 are located.

A partition wall 118 between the scan room 102 and the equipment room 104 is fitted with an RF penetration panel 120 for communicating coolant piping and electrical cables between the scan room 102 and the equipment room 104 without compromising the RF shielding of the scan room 102. The MRI system employs a power supply coupling system.

In this respect, a water cooler cabinet 122 is sited in the equipment room 104 away from any significant magnetic field influence of the superconducting magnet unit 108. A portable power supply 124 is also located within the equipment room 104; the power supply 124 is air-cooled in this example. Of course, the skilled person should appreciate that the power supply 124 need not be portable and can be permanently installed in the equipment room 104. One or more system electronics cabinets house a magnet supervisory system and other control and measurement equipment which control operation of the superconducting magnet. The superconducting magnet unit 108 also includes other equipment, for example field coils, shim coils and a patient table. However, these features of the MRI system 100 are understood to exist by the skilled person and so, for the sake of clarity and conciseness of description, will not be described further herein.

The gradient coils 116 are current-carrying and, as such, generate in the order of 20 KW of heat. Consequently, it is necessary to cool the gradient coils 116 in order to, inter alia, prevent heating of the superconducting magnet, which is maintained at a very low temperature as mentioned previously. In a first embodiment, the water cooler cabinet 122 is therefore coupled to a cooling circuit 126 formed from rubber tubing or any other suitable elastomeric material, the cooling circuit 126 extending, in part, into the ceiling void 107. A first outward branch 128 of the cooling circuit 126 therefore extends into the ceiling void 107 and passes directly through the RF penetration panel 120. The first branch 128 then continues passing through the ceiling void 107 before dropping down through the false ceiling 106 on the scan room side and being coupled to an appropriate first port (not shown) provided for cooling of the gradient coils 116. Similarly, a second return branch 130 of the cooling circuit 126 extends into the ceiling void 107 on the equipment room side and also passes directly through the RF penetration panel 120. The second branch 130 then continues passing through the ceiling void 107 before dropping down through the false ceiling 106 on the scan room side and being coupled to an appropriate second port (not shown) provided for cooling of the gradient coils 116.

A first ramp lead 132 is coupled to a negative terminal 134 of the power supply 124 and extends into the ceiling void 107 before passing through a removable sub-panel in the RF penetration panel 120 for coupling on the scan room side of the RF penetration panel 120. Similarly, a second ramp lead 136 is coupled to a positive terminal 138 of the power supply 124 and also extends into the ceiling void 107 before passing through the removable sub-panel in the RF penetration panel 120 for coupling on the scan room side of the RF penetration panel 120.

At the scan room side of the RF penetration panel 120, a first electrical conductor 140 is fitted at a first end thereof with a first coupling 142 and coupled to the positive polarity second ramp lead 136 via the first coupling 142. A second end of the first electrical conductor 140 is coupled to a suitable first connector (not shown) in the turret 112 reserved for a positive polarity connection to the coils (not shown) of the superconducting magnet within the cryostat 110. Similarly, a second electrical conductor 144 is fitted at a first end thereof with a second coupling 146 and coupled to the negative polarity first ramp lead 132 via the second coupling 146. A second end of the second electrical conductor 144 is coupled to a suitable second connector (not shown) in the turret 112 reserved for a negative polarity connection to the coils (not shown) of the superconducting magnet within the cryostat 110.

Of course, if the power supply 124 is not to be removed, the skilled person should appreciate that the first and second ramp leads 132, 136 should be coupled to the second and first electrical conductors 140, 144, respectively, via filtered connectors and not directly through the removable sub-panel of the RF penetration panel 120.

The first and second electrical conductors 140, 144 are tubular and therefore each comprises a bore through which a cooling fluid, for example water, can flow. In this example, the first and second electrical conductors 140, 144 are formed from any suitable electrically conductive material, for example copper, and are resiliently deformable. However, any suitable degree of flexibility can be provided that is permitted by the material used.

A first fluid access port 148 is provided at the first end of the first electrical conductor 140 and fluidly couples the bore of the first electrical conductor 140 with a first tap point 150 of the first branch 128 of the cooling circuit 126 via a first bridging conduit 152 formed from the same material as the first branch 128. Of course, if desired, the first branch 128 can be formed so as to obviate the need for a specific fluid coupling port, for example the first tap point 150, and the first bridging conduit 152 can be integrally formed with the first branch 128.

A second fluid access port 154 is provided at the first end of the second electrical conductor 144 and fluidly couples the bore of the second electrical conductor 144 with a second tap point 156 of the second branch 130 of the cooling circuit 126 via a second bridging conduit 158 formed from the same material as the second branch 130. Of course, if desired, the second branch 130 can also be formed so as to obviate the need for a specific fluid coupling port, for example the second tap point 156, and the second bridging conduit 158 can be integrally formed with the second branch 130.

In order to prevent egress of fluid from the ends of the first and second electrical conductors 140, 144, the ends of the first and second tubular electrical conductors 140, 144 can be fitted with or integrally formed with an appropriate termination piece, or the respective bores can be formed so as to terminate before reaching the ends of the first and/or second electrical conductors 140, 144. Indeed, the termination of the bores does not necessarily have to be particularly close to the ends of the first and/or second electrical conductors 140, 144, the distance depending upon the thermal conductivity properties of the first and/or second electrical conductors 140, 144, for example about 0.2 m, though this distance can be modified depending upon the match of cross-sectional areas between the bores of the first and/or second electrical conductor 140, 144 and the respective solid end portions (terminations) thereof.

In order to provide for return of the cooling fluid, a third bridging conduit 160 is disposed at the second ends of the first and second electrical conductors 140, 144 and fluidly couples the bores of the first and second electrical conductors 140, 144. In this respect, a third fluid access port 162 is provided at the second end of the first electrical conductor 140 and a fourth fluid access port 164 is provided at the second end of the second electrical conductor 144, the third bridging conduit 160 being coupled to the third and fourth fluid access ports 162, 164 at respective ends thereof. The third bridging conduit 160 is formed, in this example, from the same material as the first and second branches 128, 130 of the cooling circuit 126 and is an electrical insulator in order to prevent a short circuit being formed between the first and second electrical conductors 140, 144.

As will be appreciated, the first and second electrical conductors 140, 144 in combination with the third bridging conduit 160 form a separate cooling circuit that is an adjunct to the cooling circuit 126. Indeed, the separate cooling circuit formed by the first and second electrical conductors 140, 144 and the third bridging conduit 160 can be considered as a branch of or a “spur” off of the cooling circuit 126. In this example, the separate cooling circuit is dependent upon the cooling circuit 126.

In operation, the cooling fluid used to cool the gradient coils 116 circulates in the cooling circuit 126 coupled to the water cooler cabinet 122. Some of the cooling fluid is tapped off or diverted in part from the cooling circuit 126 and flows within the separate cooling circuit provided by the first and second electrical conductors 140, 144 and the third bridging conduit 160. Consequently, a proportion of the cooling fluid tapped off of the first branch 128 follows an outward path by flowing through the first electrical conductor 140 and then follows a return path through the second electrical conductor 144 back to the second branch 130 of the cooling circuit 126.

The first and second electrical conductors 140, 144 form part of an electrical circuit between the superconducting magnet and the power supply 124 by virtue of their respective abilities to conduct electricity. Consequently, the first and second electrical conductors 140, 144 in combination with the first and second ramp leads 132, 136 and the power supply 124 can be used to energize the superconducting magnet. As the actual energisation of superconducting magnets is known, the energisation process will not be described further herein for the sake of clarity and conciseness of description. It is sufficient to appreciate that the tubular first and second electrical conductors 140, 144 are used to conduct electrical current used to energize the superconducting magnet. The first and second electrical conductors 140, 144 do not, however, overheat due to the cooling provided by the flow of the cooling fluid through the first and second electrical conduits 140, 144. Hence, the respective temperatures of the first and second electrical conductors 140, 144 are maintained within acceptable temperature limits whilst using a much reduced cross sectional area of conductor.

If desired, a flow control device, for example a valve, can be provided in the first and/or second electrical conductors 140, 144 and/or the first and second first bridging conduits 152, 158 in order to prevent flow of cooling fluid in the first and second electrical conductors 140, 144 when energisation of the superconducting magnet is complete and to conserve the cooling capacity of the water cooler cabinet 122.

Turning to FIG. 2, in another embodiment, the cooling circuit 126 is configured differently so that the rubber conduits are used to form the first and second branches 128, 130 on the equipment room side of the partition wall 118 and partially in the scan room, the first and second branches 128, 130 extending through the RF penetration panel 120. On the scan room side of the partition wall 118, the first electrical conductor 140 is used to complete the first branch 128 and the second electrical conductor 144 is used to complete the second branch 130 of the cooling circuit 126. In this respect, any suitable couplings can be employed to couple the electrically insulating portions of the first and second branches 128, 130 to the first and second electrical conductors 140, 144, respectively.

From a respective point of coupling, the first electrical conductor 140 extends through the ceiling void 107 before dropping down through the false ceiling 106 to be coupled to the appropriate first port (not shown) provided for cooling of the gradient coils 116. Similarly, after another respective point of coupling, the second electrical conductor 144 extends through the ceiling void 107 before dropping down through the false ceiling 106 to be coupled to the appropriate second port (not shown) provided for cooling of the gradient coils 116. Hence, on the scan room side of the partition wall 118, tubular electrical conductors are used in the cooling circuit for the gradient coils 116 instead of electrically insulating conduits formed from an elastomeric material. However, the first and second electrical conductors 140, 144 are terminated by electrically non-conductive flexible conduit portions (not shown) in order to simplify installation and isolate the first and second electrical conductors 140, 144 from the gradient coils 116.

The first electrical conductor 140 is fitted at the first end thereof with the first coupling 142, but in this embodiment including a first patch lead 200, and coupled via the first coupling 142 to the second ramp lead 136 via the sub-panel of the RF penetration panel 120. The second electrical conductor 144 is fitted at the first end thereof with the second coupling 146, but in this embodiment including a second patch lead 202, and coupled via the second coupling 146 to the first ramp lead 132 via the sub-panel of the RF penetration panel 120. At the second end of the first electrical conductor 140, a third coupling 204 is fitted, including in this embodiment a third patch lead 206, and is coupled to the suitable first connector (not shown) in the turret 112 reserved for the positive polarity connection to the coils (not shown) of the superconducting magnet within the cryostat 110. Similarly, at the second end of the second electrical conductor 144, a fourth coupling 208 is fitted, and including in this embodiment a fourth patch lead 210, and is coupled to the suitable second connector (not shown) in the turret 112 reserved for the negative polarity connection to the coils (not shown) of the superconducting magnet within the cryostat 110.

In operation, the first and second electrical conductors 140, 144 provided serve to assist in the delivery of the cooling fluid to the gradient coils 116, but also serve as electrical conductors for the purpose of energizing the superconducting magnet instead of the deploying separate ramp leads in the scan room 102.

For the avoidance of doubt, it should be appreciated that the first, second, third and fourth couplings should be construed as optionally including the first, second, third and fourth patch cables, respectively.

If desired, the power supply 124 can be water-cooled. In such an embodiment, first and second conduits 212, 214 can be tapped off of the first and second branches 128, 130 of the cooling circuit 126 and coupled to suitable fluid inlet and outlet ports of the water-cooled power supply.

It should be appreciated that the power supply 124 of the previous embodiments need not be a power supply in the traditional sense and the term can embrace any suitable source of electrical power and not just a power supply for energizing a superconducting magnet. In this respect, and referring to FIG. 3, the first and second electrical conductors 140, 144 of the previous embodiment are used to provide electrical power to the gradient coils 116. Consequently, a gradient coil “amplifier” or power supply 300 is coupled by a positive terminal 302 thereof to a first gradient coil lead 304. The first gradient coil lead 304 extends into the ceiling void 107 before being coupled to a first side of a first filtered connector port 306 of the RF penetration panel 120 designated for a positive polarity connection. Similarly, a second gradient coil lead 308 is coupled to a negative terminal 310 of the gradient coil amplifier 300 and also extends into the ceiling void 107 before being coupled to a first side of a second filtered connector port 310 of the RF penetration panel 120 designated for a negative polarity connection.

As in relation to the previous embodiment, the first electrical conductor 140 is fitted at the first end thereof with the first coupling that includes the first patch lead 200, and is coupled via the first coupling to a second side of the first filtered connector port 306 of the RF penetration panel 120. The second electrical conductor 144 is fitted at the first end thereof with the second coupling that includes the second patch lead 202, and is coupled via the second coupling to a second side of the second filtered connector port 310 of the RF penetration panel 120. The second end of the first electrical conductor 140 is fitted with the third coupling that includes the third patch lead 206. In this example, the third coupling is coupled to a suitable third electrical connector (not shown) of the gradient coils 116 reserved for a positive polarity connection to the gradient coils 116. Similarly, the second end of the second electrical conductor 144 is fitted with the fourth coupling that includes the fourth patch lead 210. In this example, the fourth coupling is coupled to a suitable fourth electrical connector (not shown) of the gradient coils 116 reserved for a negative polarity connection to the gradient coils 116.

In operation, electrical power that needs to be supplied to the gradient coils 116 during operation of the MRI system 100 is provided via the first and second electrical conductors 140, 144 that form part of the cooling circuit 126 for the gradient coils 116. As the first and second electrical conductors 140, 144 are tubular, the cooling fluid flowing through the first and second electrical conductors 140, 144 serves to cool the first and second electrical conductors 140, 144.

Although reference has been made herein to the couplings being located “at” a given end of the first electrical conductor 140 and/or the second electrical conductor 144, the skilled person should appreciate that the coupling point of the couplings to the first and/or second electrical conductors 140, 144 are not intended to be limited to an absolute extremity of the first electrical conductor 140 and/or the second electrical conductor 144, but rather can be coupled “towards” a relevant end of the first electrical conductor 140 and/or the second electrical conductor 144. The distance along the first electrical conductor 140 and/or the second electrical conductor 144 where a coupling is coupled to the first electrical conductor 140 and/or the second electrical conductor 144 need only be sufficiently close to the extremity of the first electrical conductor 140 and/or the second electrical conductor 144 to ensure adequate cooling of the first electrical conductor 140 and/or the second electrical conductor 144 along their respective lengths. By the same token, the same consideration applies to the location of the point of coupling of the third bridging conduit 160 to the first electrical conductor 140 and/or the second electrical conductor 144.

The skilled person should appreciate that the first electrical conductor 140 and/or the second electrical conductor 144 can be formed from any suitable electrically conductive material, for example a metal, such as copper or aluminum.

Although specific reference has been made herein to coils of superconducting magnets and gradient coils, it should be appreciated that the electrical conductors can be used in relation to any electrical circuit, for example a circuit of a tomography system.

1. A tomography system comprising a superconducting magnet (108) and gradient coils (116), and a cooling arrangement for cooling the gradient coils by passage of cooling fluid therethrough;
a cooling circuit (126) comprising an outward branch (140) carrying cooling fluid to the gradient coils (116) and a return branch (144) carrying cooling fluid away from the gradient coils (116);
each of the outward branch (140) and the return branch (144) comprising a fluid-carrying conduit,
wherein
at least part of each of the outward branch (140) and the return branch (144) is formed of an electrically conductive conduit;
electrical connections from a power supply (124) to the superconducting magnet are provided through the electrically conductive conduits.

2. A tomography system according to claim 1 further comprising patch leads (200, 202) electrically connected between the power supply (124) and the electrically conductive conduits (104, 144).

3. A tomography system according to claim 1 further comprising patch leads (206, 210) electrically connected between the superconducting magnet and the electrically conductive conduits (104, 144).

4. A tomography system comprising a superconducting magnet (108) and gradient coils (116), and a cooling arrangement for cooling the gradient coils by passage of cooling fluid therethrough;
a cooling circuit (126) comprising an outward branch (128) carrying cooling fluid to the gradient coils (116) and a return branch (130) carrying cooling fluid away from the gradient coils (116);
each of the outward branch (128) and the return branch (130) comprising a fluid-carrying conduit,
wherein
electrical connections from a power supply (124) to the superconducting magnet are provided through first (140) and second (144) electrically conductive conduits,
a first end of the bore of the first electrically conductive conduit being fluidly coupled (152) to the bore of the outward branch; and a first end of the bore of the second electrically conductive conduit being fluidly coupled (158) to the bore of the return branch, and
an electrically isolating bridging conduit (160) is fluidly coupled between second ends of the first (140) and second (144) electrically conductive conduits,
thereby providing a cooling circuit which cools the first (140) and second (144) electrically conductive conduits.

5. A tomography system comprising a superconducting magnet (108) and gradient coils (116), and a cooling arrangement for cooling the gradient coils by passage of cooling fluid therethrough;
a cooling circuit (126) comprising an outward branch (128) carrying cooling fluid to the gradient coils (116) and a return branch (130) carrying cooling fluid away from the gradient coils (116);
each of the outward branch (128) and the return branch (130) comprising a fluid-carrying conduit,
wherein
at least part of each of the outward branch (140) and the return branch (144) is formed of an electrically conductive conduit;
electrical connections from a power supply (300) to the gradient coils (116) are provided through the electrically conductive conduits.

6. A tomography system according to claim 5 further comprising patch leads (206, 210) electrically connected between the gradient coils (116) and the electrically conductive conduits (104, 144).

7. A tomography system according to claim 2 further comprising patch leads (206, 210) electrically connected between the superconducting magnet and the electrically conductive conduits (104, 144).
